(19) United States
(12) Patent Application Publication
(10) Pub. No.: US 2024/0387352 A1
(43) Pub. Date: Nov. 21, 2024

(54) CAPACITIVE COUPLING PACKAGE STRUCTURE

(71) Applicants: Lite-On Singapore Pte. Ltd., Singapore (SG); LITE-ON TECHNOLOGY CORPORATION, TAIPEI CITY (TW)

(72) Inventors: YOU-FA WANG, Singapore (SG); TING-WEI KAO, New Taipei City (TW); CHIA-YUN LEE, New Taipei City (TW); YUAN-LUNG WU, New Taipei City (TW); PU-HAN LIN, New Taipei City (TW)

(21) Appl. No.: 18/648,672

(22) Filed: Apr. 29, 2024

(30) Foreign Application Priority Data
May 19, 2023 (CN) 202310567649.0

(51) Int. Cl. H01L 23/522; H01L 23/00; H01L 23/495; H01L 25/065

(52) U.S. Cl. CPC H01L 23/5222; H01L 23/4951; H01L 23/49575; H01L 24/08; H01L 24/48; H01L 25/0652; H01L 2224/08145; H01L 2224/08245; H01L 2224/48137; H01L 2224/48177; H01L 2924/0665; H01L 2924/182; H01L 2924/183; H01L 2924/30105

(57) ABSTRACT

A capacitive coupling package structure includes a plurality of first leads, a plurality of second leads, two first coupling plates, two second coupling plates, a first chip, a second chip, a first package member, and a second package member. The two first coupling plates and the two second coupling plates are vertically separate from each other and are partially and vertically overlapped with each other, respectively.

### CROSS-REFERENCE TO RELATED PATENT APPLICATION

This application claims the benefit of priority to China Patent Application No. 202310567649.0, filed on May 19, 2023, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a capacitive coupling package structure, and more particularly to a capacitive coupling package structure having two coupling plates that are separate from each other and have overlapping projection areas.

### BACKGROUND OF THE DISCLOSURE

Electric field coupling technology is commonly used in the existing capacitive isolator technology. Capacitive coupling is also used to manufacture semiconductor isolators. In the capacitive coupling package, a required capacitance is affected by the distance between the coupling plates, so that designing an appropriate capacitive coupling package structure plays an important part in product miniaturization.

Furthermore, a double sealing mold method is used in an existing capacitive coupling package structure, but provides limited packaging space. Therefore, how to design a capacitive coupling package structure with appropriate isolation distance for satisfying requirements on creepage distance and electrical gap is one of the most important issues for relevant personnel in the related art.

### SUMMARY OF THE DISCLOSURE

In response to the above-referenced technical inadequacies, the present disclosure provides a capacitive coupling package structure that has a simple manufacturing process, a low production cost, a small size, and is able to provide an improved isolation voltage, so as to address the issues of a larger existing capacitance due to isolation voltage of the capacitance being limited by the structures and distances of the coupling plates.

In order to solve the above-mentioned problems, one of the technical aspects adopted by the present disclosure is to provide a capacitive coupling package structure. The capacitive coupling package structure includes a plurality of first leads, a plurality of second leads, two first coupling plates, two second coupling plates, a first chip, a second chip, a first package member, and a second package member. The first chip is electrically connected to the plurality of first leads and the two first coupling plates. The second chip is electrically connected to the plurality of second leads and the two second coupling plates. The first package member encapsulates the plurality of first leads, the plurality of second leads, the first chip, the second chip, the two first coupling plates, and the two second coupling plates. The second package member encapsulates the first package member, the plurality of first leads, and the plurality of second leads. End portions of the two first coupling plates and the two second coupling plates are not exposed from the second package member. End portions of the plurality of first leads and the plurality of second leads are exposed from the second package member. The two first coupling plates and the two second coupling plates are vertically separate from each other and are partially and vertically overlapped with each other, respectively.

In order to solve the above-mentioned problems, another one of the technical aspects adopted by the present disclosure is to provide a capacitive coupling package structure. The capacitive coupling package structure includes a plurality of first leads, a plurality of second leads, two first coupling plates, two second coupling plates, a first chip, a second chip, a first package member, and a second package member. The first chip is electrically connected to the plurality of first leads and the two first coupling plates. The second chip is electrically connected to the plurality of second leads and the two second coupling plates. The first package member encapsulates the plurality of first leads, the plurality of second leads, the first chip, the second chip, the two first coupling plates, and the two second coupling plates. The second package member encapsulates the first package member, the plurality of first leads, and the plurality of second leads. End portions of the two first coupling plates and the two second coupling plates are not exposed from the second package member. End portions of the plurality of first leads and the plurality of second leads are exposed from the second package member. The two first coupling plates and the two second coupling plates are horizontally separate from each other and are partially and horizontally overlapped with each other, respectively.

In order to solve the above-mentioned problems, yet another one of the technical aspects adopted by the present disclosure is to provide a manufacturing method for a capacitive coupling package structure. The manufacturing method for a capacitive coupling package structure includes: providing a first lead frame and a second lead frame, the first lead frame including a plurality of first leads and two first coupling plates, and the second lead frame including a plurality of second leads and two second coupling plates; a plurality of first tie bars being disposed between the plurality of first leads and a plurality of second tie bars being disposed between the plurality of second leads; providing a first chip and a second chip, the first chip being electrically connected to the plurality of first leads and the two first coupling plates, and the second chip being electrically connected to the plurality of second leads and the two second coupling plates; aligning the first lead frame and the second lead frame, such that the two first coupling plates and the two second coupling plates are vertically separate from each other and are partially and vertically overlapped with each other, respectively; providing a first package member to encapsulate the plurality of first leads, the plurality of second leads, the two first coupling plates, the two second coupling plates, the first chip, and the second chip; cutting the plurality of first tie bars, the plurality of second tie bars, the two first coupling plates, and the two second coupling plates; providing a second package member to encapsulate the first package member, the plurality of first leads, and the plurality of second leads, such that end portions of the two first coupling plates and the two second coupling plates are not exposed from the second package member; cutting the plurality of first leads and the plurality of second leads.

In order to solve the above-mentioned problems, still another one of the technical aspects adopted by the present disclosure is to provide a manufacturing method for a capacitive coupling package structure. The manufacturing method for a capacitive coupling package structure includes: providing a first lead frame and a second lead frame, the first lead frame including a plurality of first leads and two first coupling plates, and the second lead frame including a plurality of second leads and two second coupling plates; a plurality of first tie bars being disposed between the plurality of first leads and a plurality of second tie bars being disposed between the plurality of second leads; providing a first chip and a second chip, the first chip being electrically connected to the plurality of first leads and the two first coupling plates, and the second chip being electrically connected to the plurality of second leads and the two second coupling plates; aligning the first lead frame and the second lead frame, such that the two first coupling plates and the two second coupling plates are horizontally separate from each other and are partially and horizontally overlapped with each other, respectively; providing a first package member to encapsulate the plurality of first leads, the plurality of second leads, the two first coupling plates, the two second coupling plates, the first chip, and the second chip; cutting the plurality of first tie bars, the plurality of second tie bars, the two first coupling plates, and the two second coupling plates; providing a second package member to encapsulate the first package member, the plurality of first leads, and the plurality of second leads, such that end portions of the two first coupling plates and the two second coupling plates are not exposed from the second package member; cutting the plurality of first leads and the plurality of second leads.

In order to solve the above-mentioned problems, still yet another one of the technical aspects adopted by the present disclosure is to provide a manufacturing method for a capacitive coupling package structure. The manufacturing method for a capacitive coupling package structure includes: providing a co-planar lead frame, the co-planar lead frame including a plurality of first leads, a plurality of second leads, two first coupling plates, and two second coupling plates; a plurality of first tie bars being disposed between the plurality of first leads, a plurality of second tie bars being disposed between the plurality of second leads, and the two first coupling plates being connected to the two second coupling plates, respectively; separating the two first coupling plates from the two second coupling plates, such that the two first coupling plates and the two second coupling plates are horizontally separate from each other and are partially and horizontally overlapped with each other, respectively; providing a first chip and a second chip, the first chip being electrically connected to the plurality of first leads and the two first coupling plates, and the second chip being electrically connected to the plurality of second leads and the two second coupling plates; providing a first package member to encapsulate the plurality of first leads, the plurality of second leads, the two first coupling plates, the two second coupling plates, the first chip, and the second chip; cutting the plurality of first tie bars, the plurality of second tie bars, the two first coupling plates, and the two second coupling plates; providing a second package member to encapsulate the first package member, the plurality of first leads, and the plurality of second leads, such that end portions of the two first coupling plates and the two second coupling plates are not exposed from the second package member; cutting the plurality of first leads and the plurality of second leads.

Therefore, in the capacitive coupling package structure, by virtue of “end portions of the two first coupling plates and the two second coupling plates being not exposed from the second package member,” “end portions of the plurality of first leads and the plurality of second leads being exposed from the second package member,” and “the two first coupling plates and the two second coupling plates being vertically separate from each other and being partially and vertically overlapped with each other, respectively,” a miniaturization effect of the capacitive coupling package structure can be achieved, and requirements for creepage and clearance can be met by the capacitive coupling package structure of the present disclosure.

Moreover, another one of the beneficial effects of the present disclosure is that, a manufacturing method for a capacitive coupling package structure having the aforementioned advantages is provided.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a capacitive coupling package structure according to one embodiment of the present disclosure;

FIG. 2 is a schematic view of a capacitive coupling package structure according to one embodiment of the present disclosure;

FIG. 3 is a schematic view of a capacitive coupling package structure according to one embodiment of the present disclosure;

FIG. 4 is a schematic view of a capacitive coupling package structure according to one embodiment of the present disclosure;

FIG. 5 to FIG. 9 are schematic side views of a capacitive coupling package structure according to one embodiment of the present disclosure;

FIG. 10 is a schematic view of a capacitive coupling package structure according to one embodiment of the present disclosure;

FIG. 11 is a schematic view of a capacitive coupling package structure according to one embodiment of the present disclosure;

FIG. 12 is a schematic view of a capacitive coupling package structure according to one embodiment of the present disclosure;

FIG. 13 to FIG. 15 are schematic side views of a capacitive coupling package structure according to one embodiment of the present disclosure; and

FIG. 16 to FIG. 18 are flowcharts of a manufacturing method for a capacitive coupling package structure according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

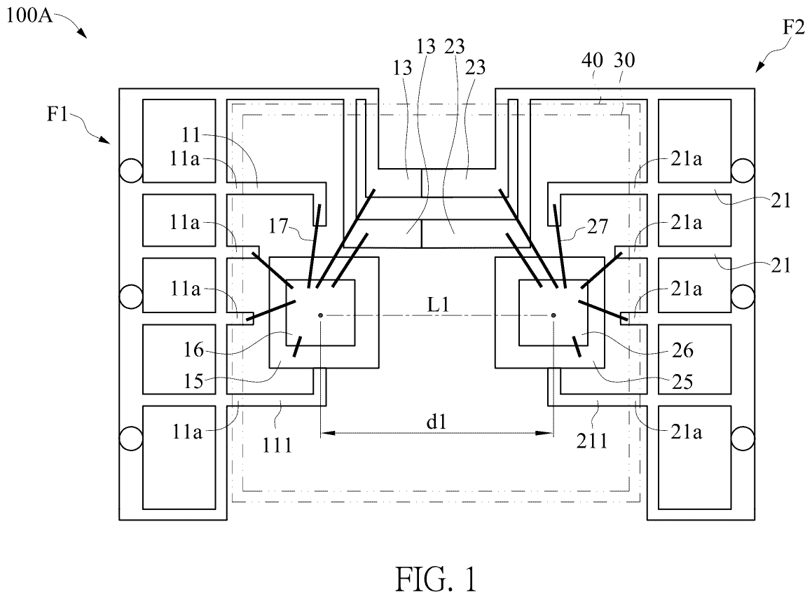

Referring to FIG. 1, FIG. 1 is a schematic view of a capacitive coupling package structure 100A according to one embodiment of the present disclosure. The capacitive coupling package structure 100A includes a plurality of first leads 11, a plurality of second leads 21, two first coupling plates 13, two second coupling plates 23, a first chip 16, a second chip 26, a first package member 30, and a second package member 40. The first chip 16 is electrically connected to the plurality of first leads 11 and the two first coupling plates 13. The second chip 26 is electrically connected to the plurality of second leads 21 and the two second coupling plates 23. The first package member 30 encapsulates the plurality of first leads 11, the plurality of second leads 21, the first chip 26, the second chip 26, the two first coupling plates 13, and the two second coupling plates 23. The second package member 40 encapsulates the first package member 30, the plurality of first leads 11, and the plurality of second leads 21. End portions of the two first coupling plates 13 and the two second coupling plates 23 are not exposed from the second package member 40. End portions of the plurality of first leads 11 and the plurality of second leads 21 are exposed from the second package member 40. The two first coupling plates 13 and the two second coupling plates 23 are vertically separate from each other and are partially and vertically overlapped with each other (details thereof will be described below), respectively. As shown in FIG. 1, the first chip 16 can be electrically connected to the plurality of first leads 11 and the two first coupling plates 13 via soldering wires 17, the second chip 26 can be electrically connected to the plurality of second leads 21 and the two second coupling plates 23 via soldering wires 27, and the first chip 16 is spaced apart from the second chip 26 by a horizontal distance d1.

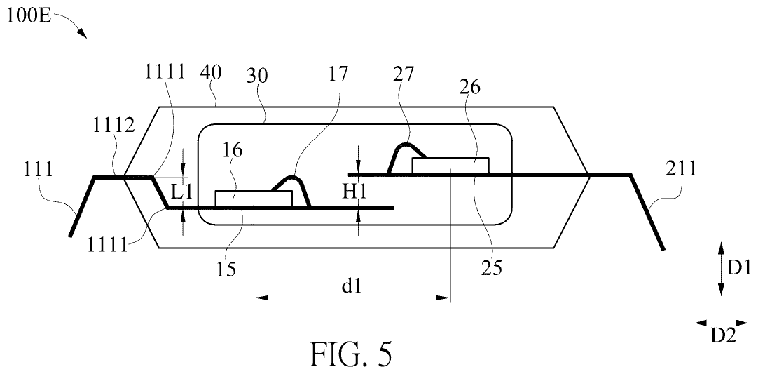

In this embodiment, the capacitive coupling package structure 100A further includes a first placement pad 15 and a second placement pad 25, the first chip 16 is fixed to the first placement pad 15, and the second chip 26 is fixed to the second placement pad 25. In addition, the plurality of first leads 11 include a first placement pad lead 111, and the first placement pad 15 is connected to the first placement pad lead 111. The plurality of second leads 21 include a second placement pad lead 211, and the second placement pad 25 is connected to the second placement pad lead 211. In certain embodiments, the first placement pad 15 and the second placement pad 25 are disposed at a same height along a vertical direction D1 (as shown in FIG. 5). In other embodiments, the first placement pad 15 and the second placement pad 25 have a height difference therebetween. The aforementioned height difference is greater than 200 μm; however, according to certain embodiments, the aforementioned height difference is greater than or equal to 400 μm.

According to the embodiment as shown in FIG. 1, a center of the first chip 16 and a center of the second chip 26 define an axis L1 therebetween as viewed in an orthogonal projection direction (the vertical direction D1), and the two first coupling plates 13 and the two second coupling plates 23 are located on one side of the axis L1. Each of the two first coupling plates 13 and a corresponding one of the two second coupling plates 23 form a signal channel. In the embodiment as shown in FIG. 1, the two signal channels are located on one side of the axis L1.

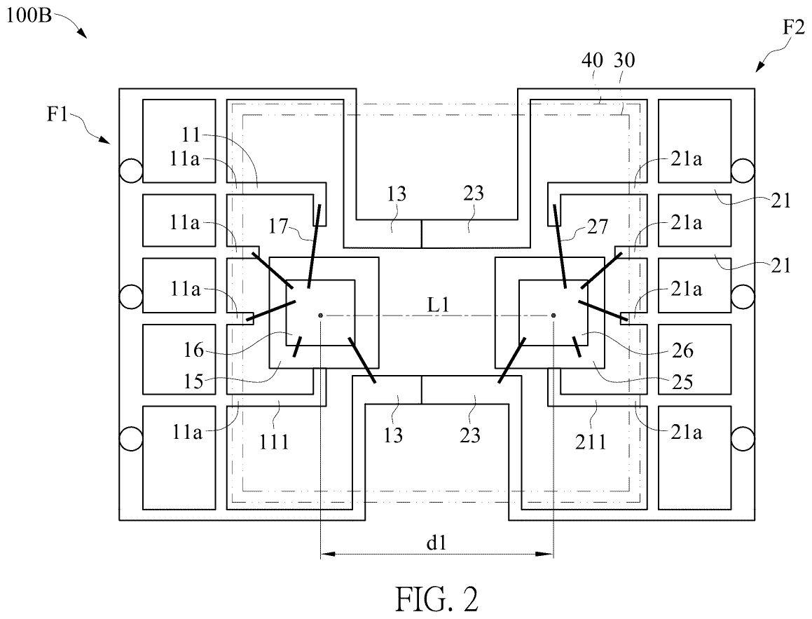

Referring to FIG. 2, FIG. 2 is a schematic view of a capacitive coupling package structure 100B according to one embodiment of the present disclosure. In this embodiment, the two first coupling plates 13 and the two second coupling plates 23 are located on two sides of the axis L1, respectively. That is, the two signal channels are located on the two sides of the axis L1, respectively.

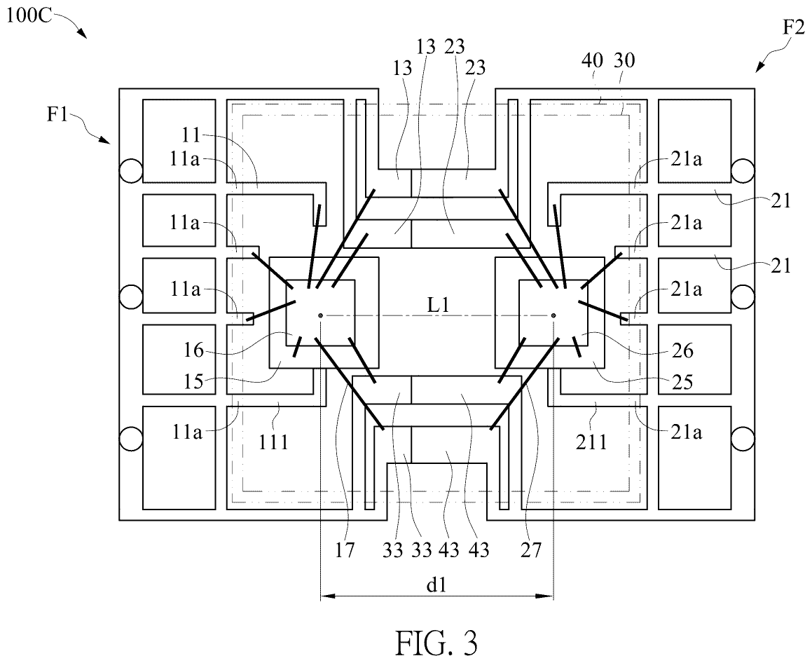

Referring to FIG. 3, FIG. 3 is a schematic view of a capacitive coupling package structure 100C according to one embodiment of the present disclosure. In this embodiment, the capacitive coupling package structure 100C further includes two third coupling plates 33 and two fourth coupling plates 43. The two third coupling plates 33 and the two fourth coupling plates 43 are vertically separate from each other, and are partially and vertically overlapped with each other (details thereof will be described below). The two third coupling plates 33 and the two fourth coupling plates 43 are located on another side of the axis L1. By such a structural design, the capacitive coupling package structure 100C can include four signal channels.

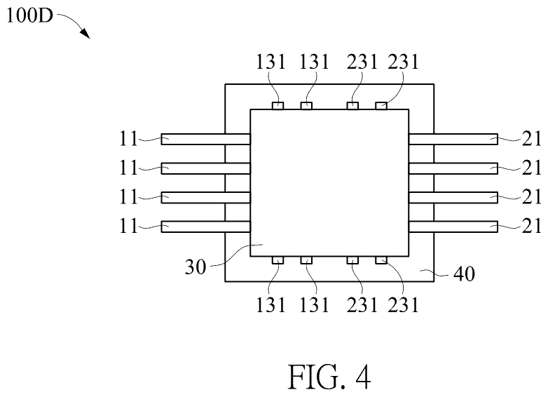

Referring to FIG. 4, FIG. 4 is a schematic view of a capacitive coupling package structure 100D according to one embodiment of the present disclosure. In this embodiment, end portions 131 of the two first coupling plates 13 and end portions 231 of the two second coupling plates 23 are exposed from the first package member 30, and are encapsulated by the second package member 40. In the aforementioned descriptions, the end portions 131 and 231 are not exposed from the second package member 40, indicating that the end portions 131 and 231 are located in the second package member 40 (as shown in FIG. 4). However, the present disclosure is not limited thereto. In certain embodiments, the end portions 131 of the two first coupling plates 13 and the end portions 231 of the two second coupling plates 23 are flush with the second package member 40 (not shown in the figures). In the embodiment as shown in FIG. 4, end portions 331 of the two third coupling plates 33 and end portions 431 of the two fourth coupling plates 43 are exposed from the first package member 30, and are encapsulated by the second package member 40.

Referring to FIG. 5, FIG. 5 is a schematic side view of a capacitive coupling package structure 100E according to one embodiment of the present disclosure. In this embodiment, the two first coupling plates 13 and the two second coupling plates 23 have a first vertical distance H1 therebetween, and the first vertical distance H1 is greater than 200 μm. In certain embodiments, the first vertical distance H1 is greater than or equal to 400 μm. A vertical distance refers to a distance in the vertical direction D1. In a dual package space formed by the first package member 30 and the second package member 40, a space is limited, such that requirements of creepage and clearance can be met for the capacitive coupling package structure 100E within the aforementioned vertical distance range. Similarly, as shown in FIG. 3, in certain embodiments, the two third coupling plates 33 and the two fourth coupling plates 43 have a second vertical distance therebetween (not shown in the figures), and the second vertical distance is greater than 200 μm. In certain embodiments, the second vertical distance is greater than or equal to 400 μm. Accordingly, in a dual package space formed by the first package member 30 and the second package member 40, a space in limited, such that isolation requirements can be met for the capacitive coupling package structure 100E within the aforementioned vertical distance range.

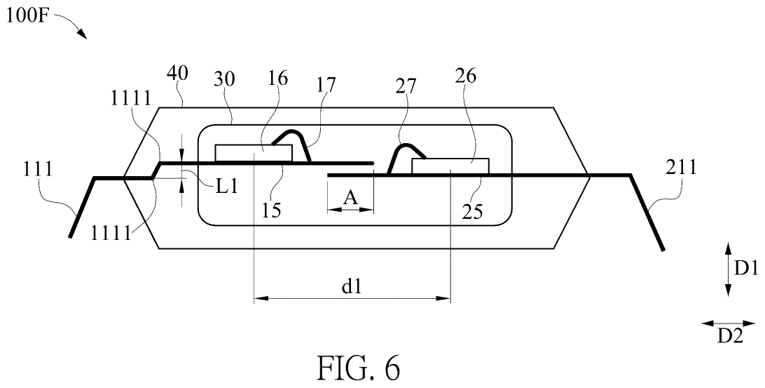

Referring to FIG. 6, FIG. 6 is a schematic side view of a capacitive coupling package structure 100F according to one embodiment of the present disclosure. In this embodiment, the two first coupling plates 13 and the two second coupling plates 23 have a first vertical overlapping area A therebetween, such that a capacitance formed between each of the two first coupling plates 13 and a corresponding one of the two second coupling plates 23 according to the first vertical overlapping area A is greater than 10 fF (fF is referred to as femtofarad, which is a unit below pF, and 1 pF=1000 fF). The first vertical overlapping area A is an overlapping area of the two first coupling plates 13 and the two second coupling plates 23 projected along the vertical direction D1 on a plane parallel to a horizontal direction D2. Within a range of the first vertical overlapping area A, an effect of miniaturization of the capacitive coupling package structure 100F can be achieved, and requirements of creepage and clearance can be met for the capacitive coupling package structure 100F. Similarly, referring to FIG. 3, in certain embodiments, the two third coupling plates 33 and the two fourth coupling plates 43 have a second vertical overlapping area (not shown in the figures) therebetween, such that a capacitance formed between each of the two third coupling plates 33 and a corresponding one of the two fourth coupling plates 43 according to the second vertical overlapping area is greater than 10 fF. In certain embodiments, the second vertical overlapping area is equal to the first vertical overlapping area A.

Reference is further made to FIG. 4 and FIG. 5. In certain embodiments, the two third coupling plates 33 and the two fourth coupling plates 43 have a second vertical distance therebetween (not shown in the figures), and the second vertical distance is greater than 200 μm. In certain embodiments, the second vertical distance is greater than or equal to 400 μm. Accordingly, in a dual package space formed by the first package member 30 and the second package member 40, a space in limited, such that isolation requirements can be met for the capacitive coupling package structure within the aforementioned vertical distance range.

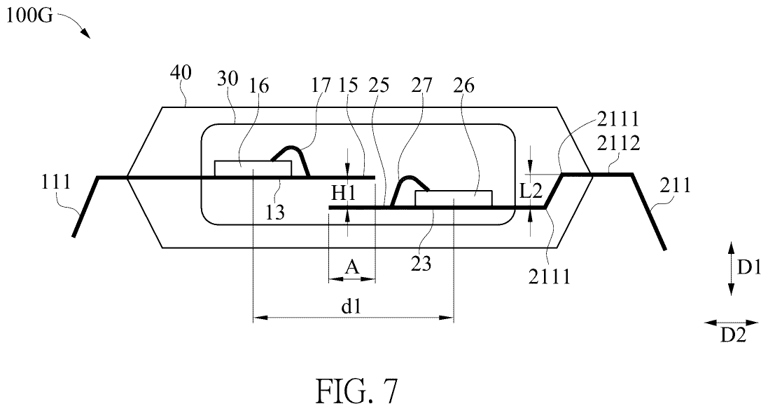

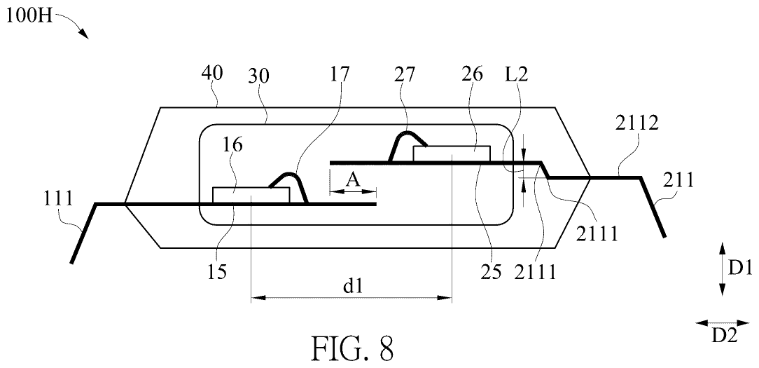

Referring to FIG. 7 and FIG. 8, FIG. 7 and FIG. 8 are side views of capacitive coupling package structures 100G and 100H according to embodiments of the present disclosure. One of the differences between FIG. 7 and FIG. 8 is that, relative positions of the two first coupling plates 13 and the two second coupling plates 23 are different in the vertical direction D1. The two first coupling plates 13 and the two second coupling plates 23 have the first vertical distance H1 therebetween, and the first vertical distance H1 equals to the height difference between the first placement pad 15 and the second placement pad 25.

According to certain embodiments, at least one of the first placement pad lead 111 and the second placement pad lead 211 has two bent portions. In the embodiments as shown in FIG. 7 and FIG. 8, the second placement pad lead 211 has two bent portions 2111, such that the first placement pad 15 and the second placement pad 25 have the aforementioned height difference therebetween. The two bent portions 2111 are located outside the first package member 30, and are encapsulated by the second package member 40.

Furthermore, the second placement pad lead 211 has a body portion 2112 in addition to the two bent portions 2111, and a turning angle is defined between one of the two bent portions 2111 and the body portion 2112. Naturally, the present disclosure is not limited to only the second placement pad lead 211 having the two bent portions 2111. According to certain embodiments, the first placement pad lead 111 and the second placement pad lead 211 both have bent portions. In other embodiments, at least one of the first placement pad lead 111 and the second placement pad lead 211 has bent portions, and another one of the first placement pad lead 111 and the second placement pad lead 211 does not have bent portions. However, the present disclosure is not limited thereto.

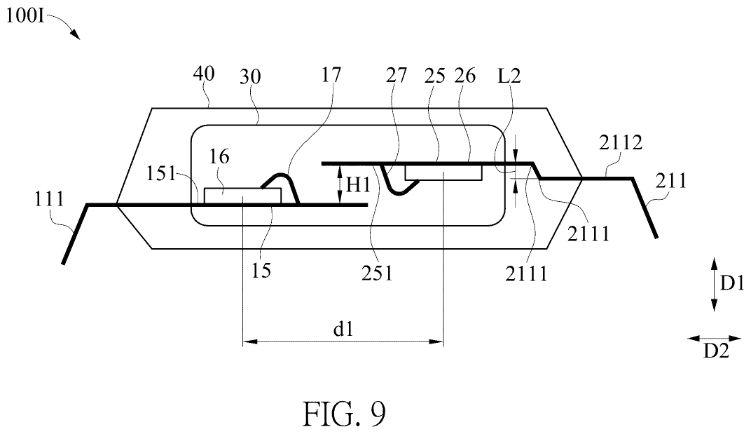

Referring to FIG. 9, FIG. 9 is a schematic side view of a capacitive coupling package structure 100I according to one embodiment of the present disclosure. In this embodiment, the first placement pad 15 has a first placement surface 151, the second placement pad 25 has a second placement surface 251, and the first placement surface 151 and the second placement surface 151 face each other. In other words, the first chip 16 is opposite to the second chip 26 on the vertical direction D1. Therefore, an effect of miniaturization of the capacitive coupling package structure 100I can be achieved, and requirements of creepage and clearance can be met for the capacitive coupling package structure 100I.

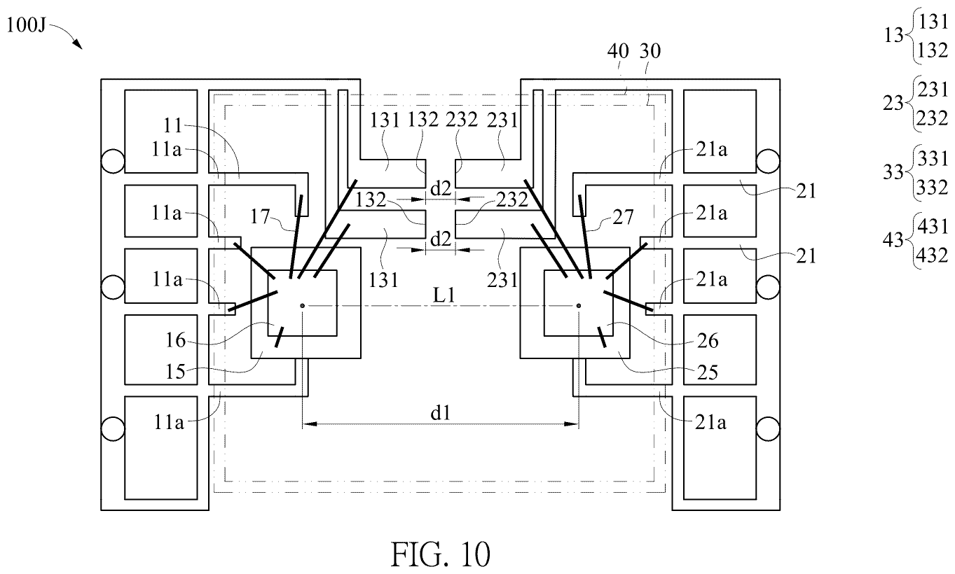

Referring to FIG. 10, FIG. 10 is a schematic view of a capacitive coupling package structure 100J according to one embodiment of the present disclosure. One of the differences between this embodiment and the embodiments as shown in FIG. 3 is that, the two first coupling plates 13 are perpendicular to a plane defined by the plurality of first leads 11, and the two second coupling plates 23 are perpendicular to a plane defined by the plurality of second leads 21. The two first coupling plates 13 and the two second coupling plates 23 are horizontally separate from each other and are partially and horizontally overlapped with each other, respectively (details thereof will be described below).

According to the embodiment as shown in FIG. 10, a center of the first chip 16 and a center of the second chip 26 define an axis L1 therebetween as viewed in an orthogonal projection direction (the vertical direction D1), and the two first coupling plates 13 and the two second coupling plates 23 are located on one side of the axis L1. Each of the two first coupling plates 13 and a corresponding second coupling plate 23 form a signal channel.

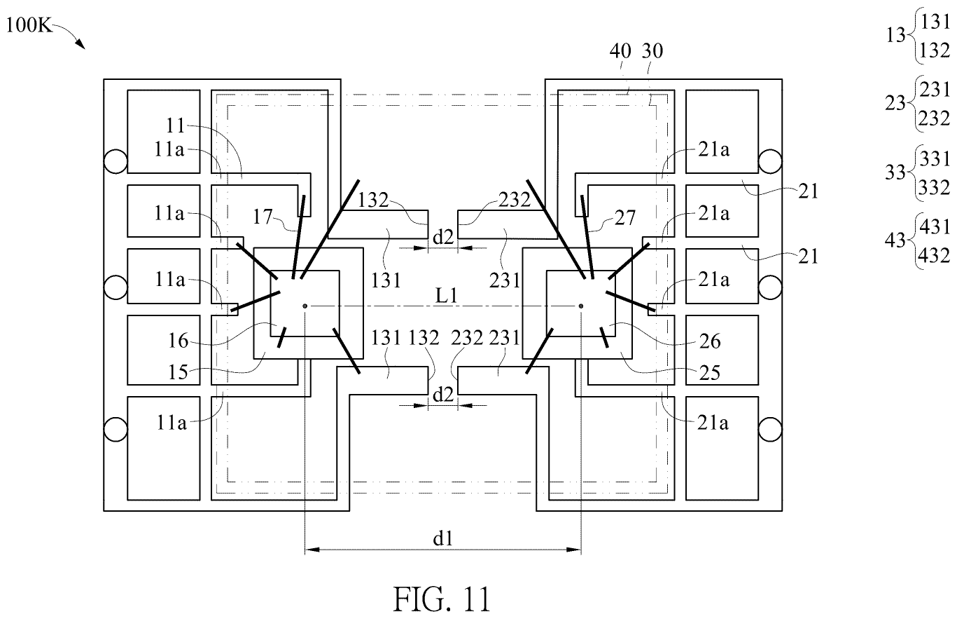

Referring to FIG. 11, FIG. 11 is a schematic view of a capacitive coupling package structure 100K according to one embodiment of the present disclosure. In this embodiment, the two first coupling plates 13 and the two second coupling plates 23 are located on two sides of the axis L1, respectively. That is, the two signal channels are located on the two sides of the axis L1, respectively. In this embodiment, the two signal channels are not limited to being located on the same side or on different sides of the axis L1.

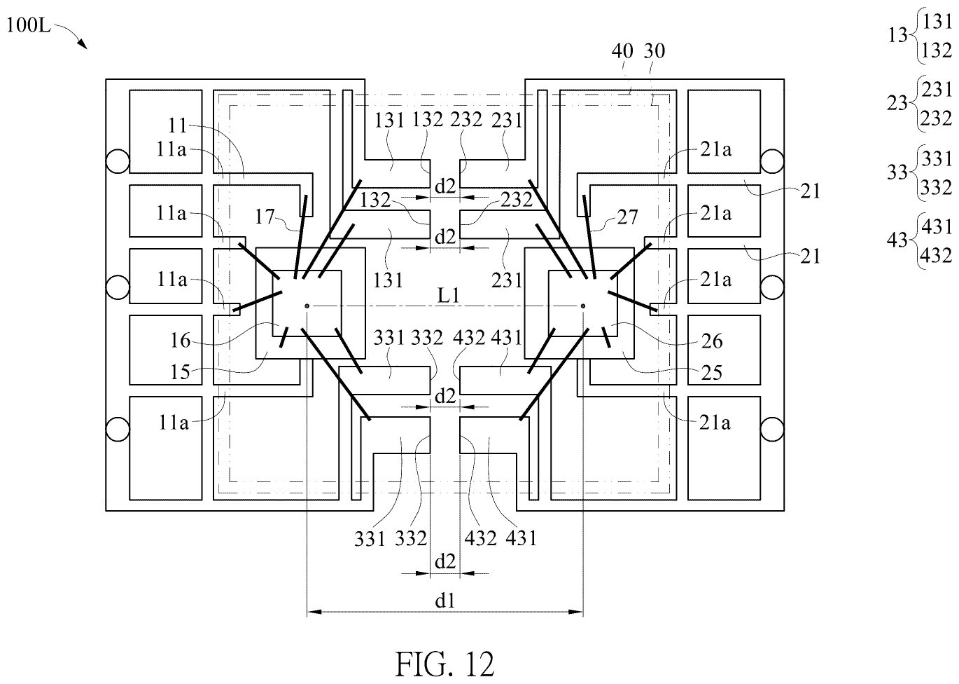

Referring to FIG. 12, FIG. 12 is a schematic view of a capacitive coupling package structure 100L according to one embodiment of the present disclosure. In this embodiment, the capacitive coupling package structure 100L further includes the two third coupling plates 33 and the two fourth coupling plates 43, and the two third coupling plates 33 and the two fourth coupling plates 43 are horizontally separate from each other and are partially and horizontally overlapped with each other, respectively (details thereof will be described below). The two third coupling plates 33 and the two fourth coupling plates 43 are located on another side of the axis L1. The two third coupling plates 33 are perpendicular to the plane defined by the plurality of first leads 11, and the two fourth coupling plates 43 are perpendicular to a plane defined by the plurality of second leads 21. By such a structural design, the capacitive coupling package structure 100L has four signal channels.

In this embodiment, the capacitive coupling package structure 100L further includes the first placement pad 15 and the second placement pad 25. The first chip 16 is fixed to first placement pad 15 and the second chip 26 is fixed to the second placement pad 25. In addition, the plurality of first leads 11 include a first placement pad lead 111, and the first placement pad 15 is connected to the first placement pad lead 111. The plurality of second leads 21 include a second placement pad lead 211, and the second placement pad 25 is connected to the second placement pad lead 211.

Similarly, referring to FIG. 2, the end portions of the two first coupling plates 13 and the two second coupling plates 23 (i.e., the end portions 131 of the two first coupling plates 13 and the end portions 231 of the two second coupling plates 23) of the capacitive coupling package structure 100L are exposed from the first package member 30, and are encapsulated by the second package member 40. Furthermore, the end portions 331 of the two third coupling plates 33 and the end portions 431 of the two fourth coupling plates 43 are exposed from the first package member 30, and are encapsulated by the second package member 40.

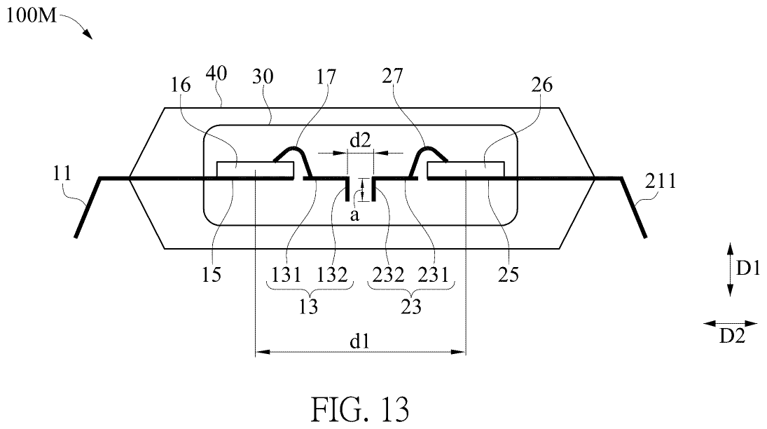

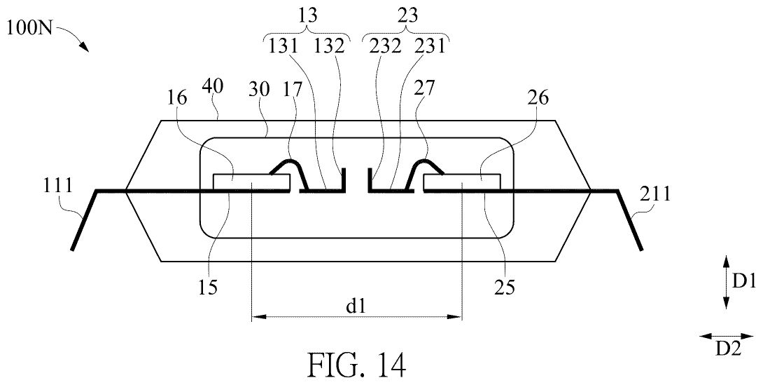

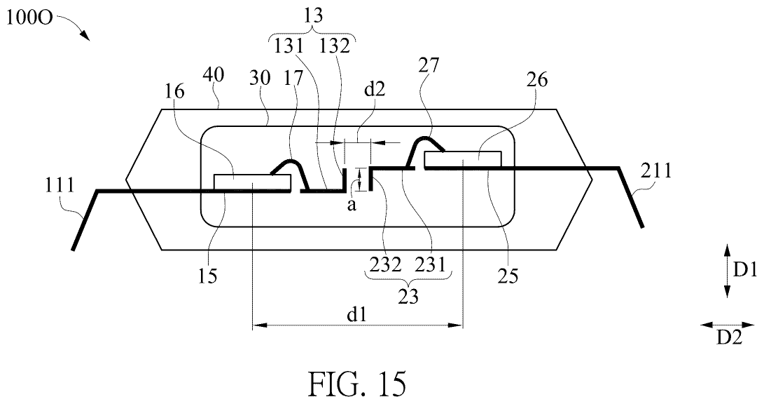

Referring to FIG. 13 to FIG. 15, FIG. 13 is a schematic side view of a capacitive coupling package structure 100M according to one embodiment of the present disclosure, FIG. 14 is a schematic side view of a capacitive coupling package structure 100N according to one embodiment of the present disclosure, and FIG. 15 is a schematic side view of a capacitive coupling package structure 100O according to one embodiment of the present disclosure. In these embodiments, the two first coupling plates 13 and the two second coupling plates 23 each have end portions (i.e., the end portions 131 of the two first coupling plates 13 and the end portions 231 of the two second coupling plates 23) and respectively have extension portions 132 and 232 that are bent. Each extension portion (i.e., each of the extension portions 132 and the extension portions 232) is substantially perpendicular to a corresponding end portion (i.e., a corresponding one of the end portions 131 and the end portions 231). The extension portions 132 of the two first coupling plates 13 and the extension portions 232 of the two second coupling plates 23 have a second horizontal distance d2 therebetween, and the second horizontal distance d2 is greater than 200 μm. According to certain embodiments, the second horizontal distance d2 is greater than or equal to 400 μm. Furthermore, in this embodiment, the two first coupling plates 13 and the two second coupling plates 23 have a first horizontal overlapping area a therebetween, the first horizontal overlapping area a is an area in which the extension portions 132 and the extension portions 232 overlapping with each other along the horizontal direction D2, and the first horizontal overlapping area a allows a capacitance formed between each the two first coupling plates 13 and a corresponding one of the two second coupling plates 23 to be greater than 10 fF. In the embodiments as shown in FIG. 13 and FIG. 14, the extension portions 132 of the two first coupling plates 13 and the extension portions 232 of the two second coupling plates 23 are extended in the same direction. However, the present disclosure is not limited thereto, and according to the embodiment as shown in FIG. 15, the extension portions 132 of the two first coupling plates 13 and the extension portions 232 of the two second coupling plates 23 are extended in different directions. Furthermore, according to the embodiments as shown in FIG. 13 and FIG. 14, the first placement pad 15 and the second placement pad 25 have the same height in the vertical direction D1, and according to the embodiment as shown in FIG. 15, the first placement pad 15 and the second placement pad 25 have a height difference therebetween.

Reference is further made to 13 to FIG. 15. In certain embodiments, the two third coupling plates 33 and the two fourth coupling plates 43 of the capacitive coupling package structure each have the end portions and the extension portion that are bent (not shown in figures). Extension portions of the two third coupling plates 33 and the two fourth coupling plates 43 have a second horizontal distance therebetween, and the second horizontal distance is greater than 200 μm. According to certain embodiments, the second horizontal distance is greater than or equal to 400 μm. Furthermore, the two first coupling plates 13 and the two second coupling plates 23 have a second horizontal overlapping area therebetween, the second horizontal overlapping area is an area in which the two extension portions overlap with each other along the horizontal direction D2, and the second horizontal overlapping area allows a capacitance formed between each of the two third coupling plates 33 and a corresponding one of the two fourth coupling plates 43 to be greater than 10 fF. Similarly, the extension portion of the two third coupling plates 33 and the extension portion of the two fourth coupling plates 43 can be extended in the same direction or different directions.

Referring to FIG. 15, according to certain embodiments, at least one of the first placement pad lead 111 and the second placement pad lead 211 has two bent portions (not shown in figures), such that the first placement pad 15 and the second placement pad 25 have a height difference therebetween.

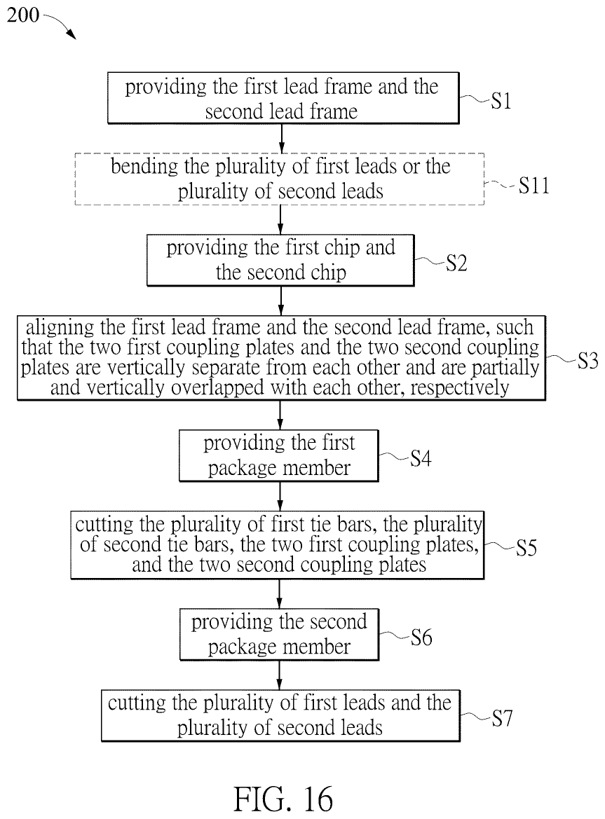

Referring to FIG. 16, which is to be read in conjunction with FIG. 3 and FIG. 4, FIG. 16 is a flowchart of a manufacturing method 200 for a capacitive coupling package structure according to one embodiment of the present disclosure. The manufacturing method 200 includes the following steps.

Step S1 includes: providing the first lead frame F1 and the second lead frame F2, the first lead frame F1 including the plurality of first leads 11 and the two first coupling plates 13, and the second lead frame F2 including the plurality of second leads 21 and the two second coupling plates 23; the plurality of first tie bars 11a being disposed between the plurality of first leads 11 and the plurality of second tie bars 21a being disposed between the plurality of second leads 21. The first lead frame F1 and the second lead frame F2 can be flat structures.

Step S2 includes: providing the first chip 16 and the second chip 26, the first chip 16 being electrically connected to the plurality of first leads 11 and the two first coupling plates 13, and the second chip 26 being electrically connected to the plurality of second leads 21 and the two second coupling plates 23.

Step S3 includes: aligning the first lead frame F1 and the second lead frame F2, such that the two first coupling plates 13 and the two second coupling plates 23 are vertically separate from each other and are partially and vertically overlapped with each other, respectively. Details regarding “the two first coupling plates 13 and the two second coupling plates 23 being vertically separate from each other and are partially and vertically overlapped with each other, respectively,” can be referred to in abovementioned descriptions of the capacitive coupling package structures.

Step S4 includes: providing the first package member 30 to encapsulate the plurality of first leads 11, the plurality of second leads 13, the two first coupling plates 13, the two second coupling plates 23, the first chip 16, and the second chip 26. In certain embodiments, a main material of the first package member 30 is epoxy resin. Furthermore, the first package member 30 is made of materials such as epoxy resin, phenolic resin, catalyst, and silica micropowder.

Step S5 includes: cutting the plurality of first tie bars 11a, the plurality of second tie bars 21a, the two first coupling plates 13 (e.g., the end portions), and the two second coupling plates 23 (e.g., the end portions).

Step S6 includes: providing the second package member 40 to encapsulate the first package member 30, the plurality of first leads 11, and the plurality of second leads 21, such that the end portions of the two first coupling plates 13 and the two second coupling plates 23 are not exposed from the second package member 40.

Step S7 includes: cutting the plurality of first leads 11 and the plurality of second leads 21. A capacitive coupling package structure is manufactured as shown in FIG. 4.

According to certain embodiments, as shown in FIG. 3, the first lead frame F1 further includes the two third coupling plates 33, and the second lead frame F2 further includes the two fourth coupling plates 43. The step S3 further includes aligning the two third coupling plates 33 and the two fourth coupling plates 43, such that the two third coupling plates 33 and the two fourth coupling plates 43 are vertically separate from each other and are partially and vertically overlapped with each other, respectively.

According to certain embodiments, before the step S2, a step S11 is performed. Step S11 includes: bending the plurality of first leads 11 or the plurality of second leads 21, such that the plurality of first leads 11 or the plurality of second leads 21 have the bent portions (as shown in FIG. 5 or FIG. 7), and a height difference is present between the first placement pad 15 and the second placement pad 25.

According to certain embodiments, before disposing the second package member 40, an inversion step is further performed (not shown in the figures). The inversion step includes: inverting the first lead frame F1 or inverting the second lead frame F2 (e.g., inverting by 180 degrees along the axis L1), such that a top surface of the first chip 16 is opposite to a top surface of the second chip 26, as shown in FIG. 9.

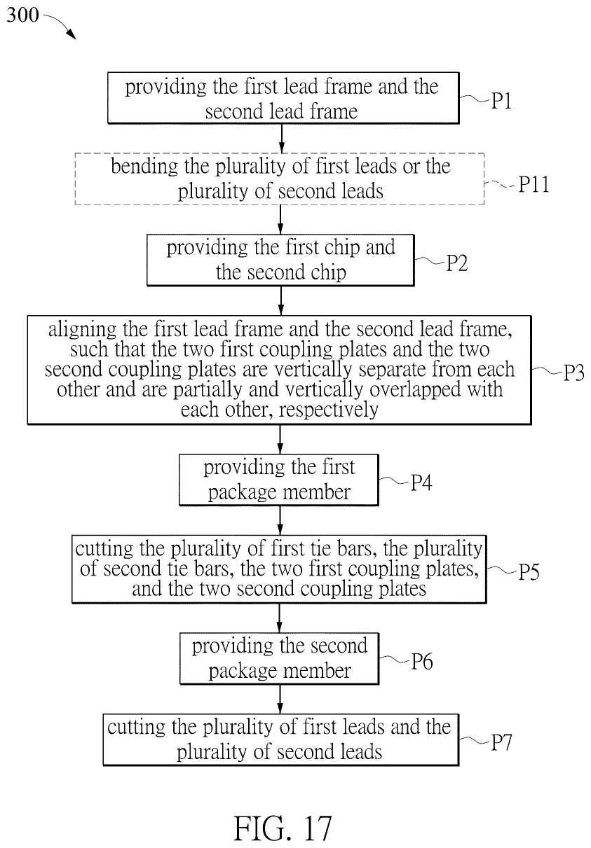

Referring to FIG. 17, which is to be read in conjunction with FIG. 11 to FIG. 14, FIG. 17 is a flowchart of a manufacturing method 300 for a capacitive coupling package structure according to one embodiment of the present disclosure. The manufacturing method 300 includes the following steps.

Step P1 includes: providing the first lead frame F1 and the second lead frame F2, the first lead frame F1 including the plurality of first leads 11 and the two first coupling plates 13, and the second lead frame F2 including the plurality of second leads 21 and the two second coupling plates 23; and the plurality of first tie bars 11a being disposed between the plurality of first leads 11, and the plurality of second tie bars 21a being disposed between the plurality of second leads 21.

Step P2 includes: providing the first chip 16 and the second chip 26, the first chip 16 being electrically connected to the plurality of first leads 11 and the two first coupling plates 13, and the second chip 26 being electrically connected to the plurality of second leads 21 and the two second coupling plates 23.

Step P3 includes: aligning the first lead frame F1 and the second lead frame F2, such that the two first coupling plates 13 and the two second coupling plates 23 are horizontally separate from each other and are partially and horizontally overlapped with each other, respectively.

Step P4 includes: providing the first package member 30 to encapsulate the plurality of first leads 11, the plurality of second leads 13, the two first coupling plates 13, the two second coupling plates 23, the first chip 16, and the second chip 26.

Step P5 includes: cutting the plurality of first tie bars 11a, the plurality of second tie bars 21a, the two first coupling plates 13, and the two second coupling plates 23.

Step P6 includes: providing the second package member 40 to encapsulate the first package member 30, the plurality of first leads 11, and the plurality of second leads 21, such that the end portions of the two first coupling plates 13 and the two second coupling plates 23 are not exposed from the second package member 40.

Step P7 includes: cutting the plurality of first leads 11 and the plurality of second leads 21.

A difference between the embodiments as shown in FIG. 16 and FIG. 17 is that, in the embodiment as shown in FIG. 16, the two first coupling plates 13 and the two second coupling plates 23 are vertically separate from each other and are partially and vertically overlapped with each other, respectively; in the embodiment as shown in FIG. 17, the two first coupling plates 13 and the two second coupling plates 23 are horizontally separate from each other and are partially and horizontally overlapped with each other, respectively.

According to certain embodiments, before the step P2 (providing the first chip 16 and the second chip 26), the two first coupling plates 13 and the two second coupling plates 23 can be bent, such that the two first coupling plates 13 and the two second coupling plates 23 are horizontally separate from each other and are partially and horizontally overlapped with each other, respectively (as shown in FIG. 13). For example, each of the extension portions 132 of the two first coupling plates 13 is opposite to and parallel with each of the extension portions 232 of the two second coupling plates 23. According to certain embodiments, the two first coupling plates 13 and the two second coupling plates 23 are bent in the same direction, as shown in FIG. 13 and FIG. 14. However, the present disclosure is not limited thereto, and according to other embodiments, the two first coupling plates 13 and the two second coupling plates 23 are bent in different directions, as shown in FIG. 15.

According to certain embodiments, before the step P2, a step P11 is performed. Step P11 includes: bending the plurality of first leads 11 or the plurality of second leads 21, such that the plurality of first leads 11 or the plurality of second leads 21 have the bent portions, and a height difference is present between the first placement pad 15 and the second placement pad 25.

According to certain embodiments, as shown in FIG. 12, the first lead frame F1 further includes the two third coupling plates 33, and the second lead frame F2 further includes the two fourth coupling plates 43. The step P3 further includes aligning the two third coupling plates 33 and the two fourth coupling plates 43, such that the two third coupling plates 33 and the two fourth coupling plates 43 are horizontally separate from each other and are partially and horizontally overlapped with each other, respectively.

According to certain embodiments, before the step S2 (providing the first chip 16 and the second chip 26), the two third coupling plates 33 and the two fourth coupling plates 43 are bent, such that each of the extension portions of the two third coupling plates 33 is opposite to and parallel with each of the extension portions of the two fourth coupling plates 43. Similarly, the two third coupling plates 33 and the two fourth coupling plates 43 can be bent in the same direction or different directions.

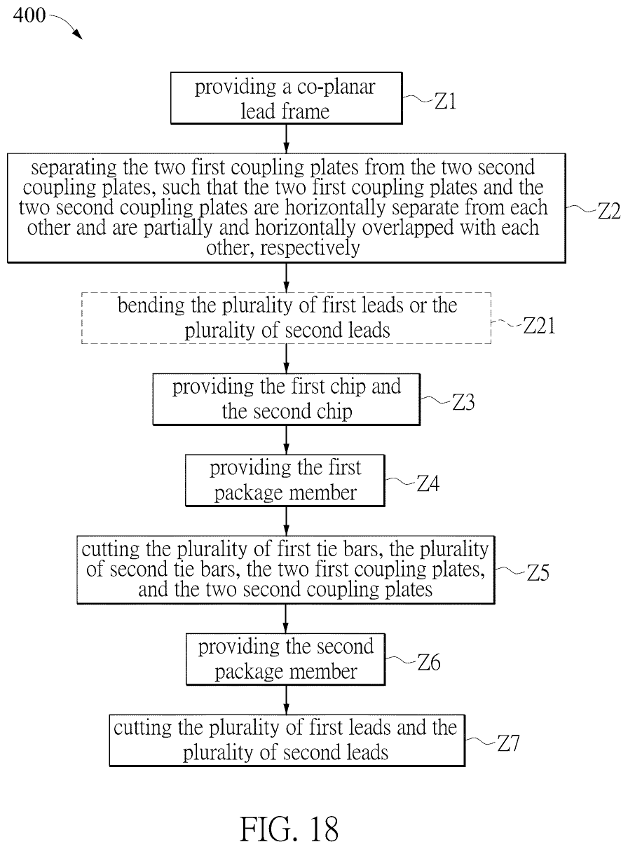

Referring to FIG. 18, which is to be read in conjunction with FIG. 12 to FIG. 15, FIG. 18 is a flowchart of a manufacturing method 400 for a capacitive coupling package structure according to one embodiment of the present disclosure. The manufacturing method 400 includes the following steps.

Step Z1 includes: providing a co-planar lead frame, the co-planar lead frame including the plurality of first leads 11, the plurality of second leads 21, the two first coupling plates 13, and the two second coupling plates 23; the two first coupling plates 13 being connected to the two second coupling plates 23, respectively; and the plurality of first tie bars 11a being disposed between the plurality of first leads 11, and the plurality of second tie bars 21a being disposed between the plurality of second leads 21.

Step Z2 includes: separating the two first coupling plates 13 from the two second coupling plates 23, such that the two first coupling plates 13 and the two second coupling plates 23 are horizontally separate from each other and are partially and horizontally overlapped with each other, respectively.

Step Z3 includes: providing the first chip 16 and the second chip 26, the first chip 16 being electrically connected to the plurality of first leads 11 and the two first coupling plates 13, and the second chip 26 being electrically connected to the plurality of second leads 21 and the two second coupling plates 23.

Step Z4 includes: providing the first package member 30 to encapsulate the plurality of first leads 11, the plurality of second leads 21, the two first coupling plates 13, the two second coupling plates 23, the first chip 16, and the second chip 26.

Step Z5 includes: cutting the plurality of first tie bars 11a, the plurality of second tie bars 21a, the two first coupling plates 13, and the two second coupling plates 23.

Step Z6 includes: providing a second package member 40 to encapsulate the first package member 30, the plurality of first leads 11, and the plurality of second leads 21, such that the end portions of the two first coupling plates 13 and the two second coupling plates 23 are not exposed from the second package member 40.

Step Z7 includes: cutting the plurality of first leads 11 and the plurality of second leads 21.

A difference between the embodiments as shown in FIG. 18 and FIG. 17 is that, the co-planar lead frame includes the first lead frame F1 and the second lead frame F2. For example, the co-planar lead frame is an integral structure, such that the two first coupling plates 13 are connected to the two second coupling plates 23. In certain embodiments, the two first coupling plates 13 can be separated from the two second coupling plates 23 by using a stamping press. Furthermore, the separation process can further include bending the two first coupling plates 13 and the two second coupling plates 23. For example, a stamping press is used to pass through a cutting opening between the two first coupling plates 13 and the two second coupling plates 23. At this time, because a width of the stamping press is greater than the cutting opening, the two first coupling plates 13 and the two second coupling plates 23 can be bent. At this time, the two first coupling plates 13 and the two second coupling plates 23 are bent in the same direction. However, in certain embodiments, the two first coupling plates 13 and the two second coupling plates 23 are bent in different directions.

According to certain embodiments, as shown in FIG. 12, the co-planar lead frame further includes the two third coupling plates 33 and the two fourth coupling plates 43. The step Z3 further includes aligning the two third coupling plates 33 and the two fourth coupling plates 43, such that the two third coupling plates 33 and the two fourth coupling plates 43 are horizontally separate from each other and are partially and horizontally overlapped with each other, respectively. In addition, the two third coupling plates 33 and the two fourth coupling plates 43 can be bent, and the two third coupling plates 33 and the two fourth coupling plates 43 can be bent in the same direction or different directions.

According to certain embodiments, before the step Z2, a step Z21 is performed. Step Z21 includes: bending the plurality of first leads 11 or the plurality of second leads 21, such that the plurality of first leads 11 or the plurality of second leads 21 have the bent portions, and a height difference is present between the first placement pad 15 and the second placement pad 25.

### Beneficial Effects of the Embodiments

In conclusion, in the capacitive coupling package structure, by virtue of “end portions of the two first coupling plates and the two second coupling plates being not exposed from the second package member,” “end portions of the plurality of first leads and the plurality of second leads being exposed from the second package member,” and “the two first coupling plates and the two second coupling plates being vertically separate from each other and being partially and vertically overlapped with each other, respectively,” a miniaturization of the capacitive coupling package structure can be achieved, and requirements for creepage and clearance can be by for the capacitive coupling package structure of the present disclosure.

Moreover, another one of the beneficial effects of the present disclosure is that, a manufacturing method for a capacitive coupling package structure having the aforementioned advantages is provided.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A capacitive coupling package structure, comprising:
a plurality of first leads;
a plurality of second leads;
two first coupling plates;
two second coupling plates;
a first chip being electrically connected to the plurality of first leads and the two first coupling plates;
a second chip being electrically connected to the plurality of second leads and the two second coupling plates;
a first package member encapsulating the plurality of first leads, the plurality of second leads, the first chip, the second chip, the two first coupling plates, and the two second coupling plates; and
a second package member encapsulating the first package member, the plurality of first leads, and the plurality of second leads;
wherein end portions of the two first coupling plates and the two second coupling plates are not exposed from the second package member;
wherein end portions of the plurality of first leads and the plurality of second leads are exposed from the second package member;
wherein the two first coupling plates and the two second coupling plates are vertically separate from each other and are partially and vertically overlapped with each other, respectively.

2. The capacitive coupling package structure according to claim 1, wherein, as viewed in an orthogonal projection direction, a center of the first chip and a center of the second chip define an axis therebetween, and the two first coupling plates and the two second coupling plates are located on two sides of the axis, respectively.

3. The capacitive coupling package structure according to claim 1, wherein, as viewed in an orthogonal projection direction, a center of the first chip and a center of the second chip define an axis therebetween, and the two first coupling plates and the two second coupling plates are located on one side of the axis.

4. The capacitive coupling package structure according to claim 1, further comprising two third coupling plates and two fourth coupling plates, wherein the two third coupling plates and the two fourth coupling plates are vertically separate from each other and are partially and vertically overlapped with each other.

5. The capacitive coupling package structure according to claim 4, wherein, as viewed in an orthogonal projection direction, a center of the first chip and a center of the second chip define an axis therebetween, the two first coupling plates and the two second coupling plates are located on one side of the axis, and the two third coupling plates and the two fourth coupling plates are located on another side of the axis.

6. The capacitive coupling package structure according to claim 1, wherein the end portions of the two first coupling plates and the two second coupling plates are exposed from of the first package member and are encapsulated by the second package member.

7. The capacitive coupling package structure according to claim 4, wherein the end portions of the two first coupling plates and the two second coupling plates, and end portions of the two third coupling plates and the two fourth coupling plates are exposed from the first package member and are encapsulated by the second package member.

8. The capacitive coupling package structure according to claim 1, wherein the two first coupling plates and the two second coupling plates have a first vertical distance therebetween, and the first vertical distance is greater than or equal to 400 μm.

9. The capacitive coupling package structure according to claim 1, wherein the two first coupling plates and the two second coupling plates have a first vertical overlapping area therebetween, such that a capacitance formed between each of the two first coupling plates and a corresponding one of the two second coupling plates is greater than 10 fF.

10. The capacitive coupling package structure according to claim 1, further comprising a first placement pad and a second placement pad, wherein the first chip is fixed to the first placement pad and the second chip is fixed to the second placement pad.

11. The capacitive coupling package structure according to claim 10, wherein the plurality of first leads include a first placement pad lead, and the first placement pad is connected to the first placement pad lead, and wherein the plurality of second leads include a second placement pad lead, and the second placement pad is connected to the second placement pad lead.

12. The capacitive coupling package structure according to claim 10, wherein the first placement pad and the second placement pad have a height difference therebetween.

13. The capacitive coupling package structure according to claim 11, wherein at least one of the first placement pad lead and the second placement pad lead has two bent portions.

14. The capacitive coupling package structure according to claim 13, wherein the two bent portions are located outside of the first package member and are encapsulated by the second package member.

15. The capacitive coupling package structure according to claim 10, wherein the first placement pad has a first placement surface, the second placement pad has a second placement surface, and the first placement surface and the second placement surface face each other.
